(19) United States
(12) Patent Application Publication
(10) Pub. No.: US 2025/0072259 A1
(43) Pub. Date: Feb. 27, 2025

(54) DISPLAY DEVICE

(71) Applicant: Samsung Display Co., Ltd., Yongin-si (KR)

(72) Inventors: MIN-SUNG KIM, Yongin-si (KR); JUNGIL LEE, Yongin-si (KR); JIHEON LEE, Yongin-si (KR); JOONGGUN CHONG, Yongin-si (KR)

(73) Assignee: Samsung Display Co., Ltd., Yongin-si (KR)

(21) Appl. No.: 18/761,639

(22) Filed: Jul. 2, 2024

(30) Foreign Application Priority Data
Aug. 21, 2023 (KR) 10-2023-0108971

(51) Int. Cl. H10K 59/80; H10K 102/00

(52) U.S. Cl. CPC H10K 59/80; H10K 2102/311

(57) ABSTRACT

Disclosed is a display device including a display panel including a first non-folding region, a folding region, and a second non-folding region sequentially disposed in a first direction, a support plate disposed below the display panel and including openings that overlap the folding region in a plan view, and an impact resistance enhancement layer disposed below the display panel. The support plate has a groove that overlaps the folding region in a plan view. The impact resistance enhancement layer is disposed in the groove of the support plate and has a modulus in a range of about 3 GPa to about 6 GPa.

### CROSS-REFERENCE TO RELATED APPLICATIONS

This application claims priority to and benefits of Korean Patent Application No. 10-2023-0108971 under 35 U.S.C. § 119 filed on Aug. 21, 2023, in the Korean Intellectual Property Office, the entire contents of which are incorporated herein by reference.

### BACKGROUND

### 1. Technical Field

Embodiments of the disclosure described herein relate to a display device, and by way of example, relate to a display device including a support plate having a groove defined thereon and an impact resistance enhancement layer disposed in the groove.

### 2. Description of the Related Art

Electronic devices, such as a smart phone, a digital camera, a notebook computer, a car navigation unit, a smart television, and the like, which provide an image to a user include a display device for displaying an image. The display device generates an image and provides the image to the user through a display screen.

With the development of display device technology, various forms of display devices are being developed. For example, various display devices that are able to be curved, folded, or rolled are being developed.

A flexible display device may include a flexible display panel and a support plate disposed under the display panel. A plurality of holes for facilitating folding may be defined in the support plate.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device including a folding region having excellent impact resistance and folding reliability while reducing the thickness of the display device and lowering the unit cost.

According to an embodiment, a display device may include a display panel including a first non-folding region, a folding region, and a second non-folding region sequentially disposed in a first direction; a support plate disposed below the display panel and that may include a plurality of openings that overlap the folding region in a plan view; and an impact resistance enhancement layer disposed below the display panel. The support plate has a groove that overlaps the folding region in a plan view. The impact resistance enhancement layer is disposed in the groove of the support plate and has a modulus in a range of about 3 GPa to about 6 GPa.

The impact resistance enhancement layer may have a thickness in a range of about 30 μm to about 50 μm.

The support plate may include an upper surface adjacent to the display panel, and the groove may be defined on the upper surface of the support plate.

The display device may further include a first adhesive layer directly disposed on the support plate and a panel protection layer directly disposed on the first adhesive layer.

The impact resistance enhancement layer may be connected with the panel protection layer through the first adhesive layer.

The impact resistance enhancement layer may not be connected with the support plate.

The display device may further include a second adhesive layer directly disposed below the impact resistance enhancement layer and that connects the impact resistance enhancement layer and the support plate.

The display device may further include an adhesive layer 1-1 directly disposed on the support plate and that overlaps the first non-folding region and does not overlap the folding region in a plan view, an adhesive layer 1-2 directly disposed on the support plate and that overlaps the second non-folding region and does not overlap the folding region in a plan view, and a panel protection layer directly disposed on the adhesive layer 1-1 and the adhesive layer 1-2.

The display device may further include a second adhesive layer disposed below the impact resistance enhancement layer and that connects the impact resistance enhancement layer and the support plate.

The impact resistance enhancement layer may not be connected with the panel protection layer.

According to an embodiment, a display device may include a display panel including a first non-folding region, a folding region, and a second non-folding region sequentially disposed in a first direction; a support plate disposed below the display panel and that may include a plurality of openings that overlap the folding region in a plan view, and an impact resistance enhancement layer disposed below the display panel. The support plate has a groove that overlaps the folding region in a plan view, and the impact resistance enhancement layer is disposed in the groove of the support plate and has a thickness in a range of about 30 μm to about 50 μm.

The impact resistance enhancement layer may have a modulus in a range of about 3 GPa to about 6 GPa.

The support plate may include an upper surface adjacent to the display panel, and the groove may be defined on the upper surface of the support plate.

The display device may further include a first adhesive layer directly disposed on the support plate and a panel protection layer directly disposed on the first adhesive layer, and the impact resistance enhancement layer may be connected with the panel protection layer through the first adhesive layer.

The display device may further include an adhesive layer 1-1 directly disposed on the support plate and that overlaps the first non-folding region and does not overlap the folding region in a plan view, an adhesive layer 1-2 directly disposed on the support plate and that overlaps the second non-folding region and does not overlap the folding region in a plan view, a panel protection layer directly disposed on the adhesive layer 1-1 and the adhesive layer 1-2, and a second adhesive layer disposed below the impact resistance enhancement layer and that connects the impact resistance enhancement layer and the support plate.

The display device may further include a first adhesive layer directly disposed on the support plate, a panel protection layer directly disposed on the first adhesive layer, and a second adhesive layer directly disposed below the impact resistance enhancement layer and that connects the impact resistance enhancement layer and the support plate.

According to an embodiment, a display device may include a display panel including a first non-folding region, a folding region, and a second non-folding region sequentially disposed in a first direction, a support plate disposed below the display panel and that may include a plurality of openings that overlap the folding region in a plan view, and an impact resistance enhancement layer disposed below the display panel. The support plate may include an upper surface adjacent to the display panel. The support plate has a groove on the upper surface that overlaps the folding region in a plan view. The impact resistance enhancement layer is disposed in the groove of the support plate.

The impact resistance enhancement layer may have a modulus in a range of about 3 GPa to about 6 GPa.

The impact resistance enhancement layer may have a thickness in a range of about 30 μm to about 50 μm.

The display device may further include a first adhesive layer directly disposed on the support plate and a panel protection layer directly disposed on the first adhesive layer.

### BRIEF DESCRIPTION OF THE DRAWINGS

The above and other objects and features of the disclosure will become apparent by describing in detail embodiments thereof with reference to the accompanying drawings in which:

FIG. 1A is a schematic perspective view illustrating an unfolded state of a display device according to an embodiment.

FIG. 1B is a schematic perspective view illustrating an in-folding process of the display device according to an embodiment.

FIG. 1C is a schematic perspective view illustrating an out-folding process of the display device according to an embodiment.

FIG. 2A is a schematic perspective view illustrating an unfolded state of a display device according to an embodiment.

FIG. 2B is a schematic perspective view illustrating an in-folding process of the display device according to an embodiment.

FIG. 3 is an exploded perspective view of a display device according to an embodiment.

FIG. 4 is a block diagram of the display device according to an embodiment.

FIG. 5 is a sectional view of a display panel according to an embodiment.

FIG. 6 is a schematic plan view of a display module according to an embodiment.

FIG. 7A is a sectional view of a display device according to an embodiment.

FIG. 7B is a schematic perspective view of a support plate according to an embodiment.

FIG. 7C is an enlarged plan view of a portion of the support plate according to an embodiment.

FIG. 8A is a sectional view illustrating a portion of a display device according to an embodiment.

FIGS. 8B and 8C are sectional views illustrating portions of display devices according to comparative examples.

FIG. 9 is a sectional view of a display device according to an embodiment.

FIG. 10 is a sectional view of a display device according to an embodiment.

### DETAILED DESCRIPTION OF THE EMBODIMENTS

Various changes may be made to the disclosure, and various embodiments may be implemented. Thus, embodiments are illustrated in the drawings and described as examples herein. However, it should be understood that the disclosure is not to be construed as being limited thereto and covers all modifications, equivalents, and alternatives falling within the spirit and scope of the disclosure.

In this specification, the singular forms, “a,” “an,” and “the” are intended to include the plural forms as well, unless the context clearly indicates otherwise.

In this specification, the terms “comprises,” “comprising,” “includes,” and/or “including,”, “has,” “have,” and/or “having,” and variations thereof specify the presence of stated features, numbers, integers, steps, operations, elements, components, parts and/or groups thereof, but do not preclude the presence or addition of one or more other features, numbers, integers, steps, operations, elements, components, parts and/or groups thereof.

In this specification, when it is mentioned that a component (or, a region, a layer, a part, etc.) is referred to as being “on”, “connected to” or “coupled to” another component, this means that the component may be directly on, connected to, or coupled to the other component or a third component may be present therebetween.

In this specification, terms such as “below”, “under”, “above”, and “over” are used to describe a relationship of components illustrated in the drawings. The terms are relative concepts and are described based on directions illustrated in the drawing.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

In this specification, the expression “disposed on” may mean that it is disposed not only on an upper portion but also a lower portion of any one member.

In this specification, the expression “directly disposed” may mean that there is no additional layer, film, area, or plate between one portion, such as a layer, a film, an area, or a plate, and another portion. For example, the expression “directly disposed” may mean that two layers or two members are disposed without an additional member such as an adhesive member therebetween.

In this specification, and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

In this specification, terms such as first, second, and the like may be used to describe various components, but the components should not be limited by the terms. The terms may be used only for distinguishing one component from other components. For example, without departing from the scope of the disclosure, a first component may be referred to as a second component, and similarly, the second component may also be referred to as the first component.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined, all terms used herein, including technical or scientific terms, have the same meanings as those generally understood by those skilled in the art to which the disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the application.

Embodiments may be described and illustrated in the accompanying drawings in terms of functional blocks, units, and/or modules.

Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies.

In the case of the blocks, units, and/or modules being implemented by microprocessors or other similar hardware, they may be programmed and controlled using software (for example, microcode) to perform various functions discussed herein and may optionally be driven by firmware and/or software.

It is also contemplated that each block, unit, and/or module may be implemented by dedicated hardware, or as a combination of dedicated hardware to perform some functions and a processor (for example, one or more programmed microprocessors and associated circuitry) to perform other functions.

Each block, unit, and/or module of embodiments may be physically separated into two or more interacting and discrete blocks, units, and/or modules without departing from the scope of the disclosure.

Further, the blocks, units, and/or modules of embodiments may be physically combined into more complex blocks, units, and/or modules without departing from the scope of the disclosure.

Identical reference numerals refer to identical components. In the drawings, the thicknesses, proportions, and dimensions of components are exaggerated for effective description.

Hereinafter, embodiments will be described with reference to the accompanying drawings.

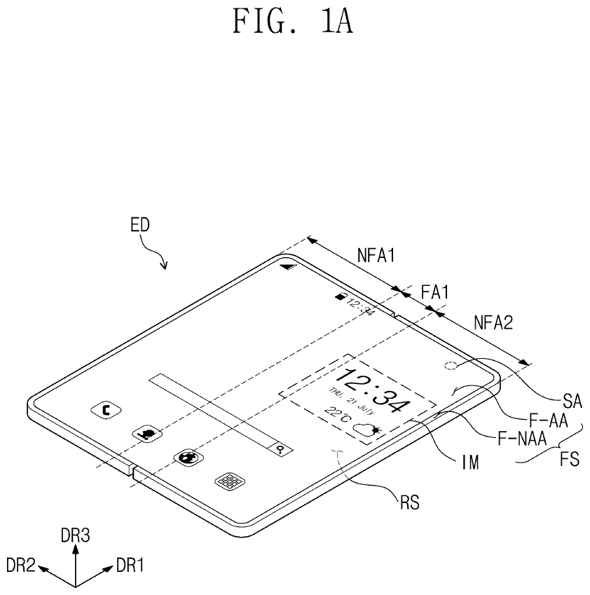

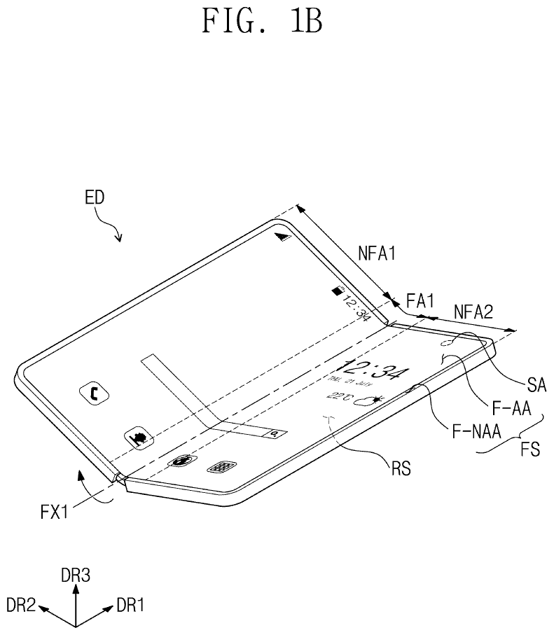

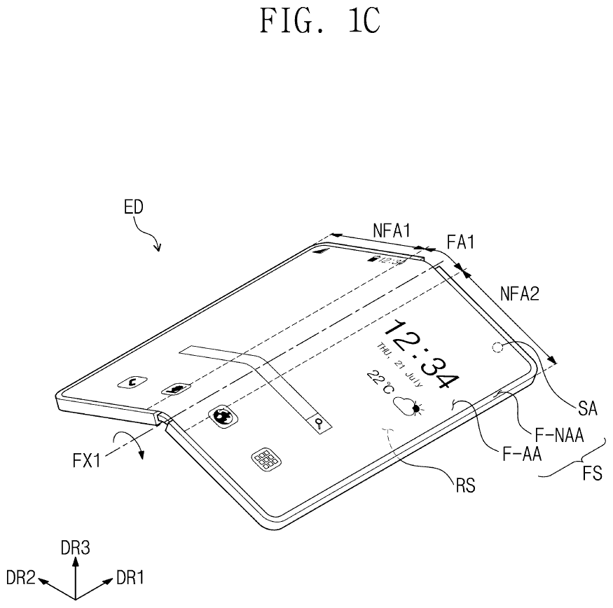

FIG. 1A is a schematic perspective view illustrating an unfolded state of a display device ED according to an embodiment. FIG. 1B is a schematic perspective view illustrating an in-folding process of the display device ED illustrated in FIG. 1A. FIG. 1C is a schematic perspective view illustrating an out-folding process of the display device ED illustrated in FIG. 1A.

The display device ED may be a device activated depending on an electrical signal. For example, the display device ED may be a mobile phone, a tablet computer, a car navigation unit, a game machine, or a wearable device. However, embodiments are not limited thereto. FIGS. 1A to IC illustrate an example that the display device ED is a mobile phone.

Although a first direction DR1, a second direction DR2, and a third direction DR3 are illustrated in FIG. 1A and the following drawings, the directions indicated by the first to third directions DR1, DR2, and DR3 described in this specification may be relative concepts and may be changed to other directions.

Referring to FIGS. 1A to IC, the display device ED according to an embodiment may include a display surface FS defined by the first direction DR1 and the second direction DR2 intersecting the first direction DR1. The display device ED may provide an image IM to a user through the display surface FS. The display device ED may display the image IM in the third direction DR3 on the display surface FS parallel to the first direction DR1 and the second direction DR2. In this specification, front surfaces (or, upper surfaces) and rear surfaces (or, lower surfaces) of components are defined based on the direction in which the image IM is displayed.

The display device ED may sense an external input applied from the outside. The external input may include various forms of inputs provided from outside the display device ED. For example, the external input may include not only contact by a part of the user's body, such as the user's hand, but also an external input (for example, hovering) that is applied in proximity to the display device ED or applied adjacent to the display device ED at a given distance. The external input may have various forms such as force, pressure, temperature, light, and the like within the spirit and the scope of the disclosure.

The display surface FS of the display device ED may include an active region F-AA and a peripheral region F-NAA. The active region F-AA may be a region activated depending on an electrical signal. The display device ED may display the image IM through the active region F-AA. The active region F-AA may sense various forms of external inputs. The peripheral region F-NAA is adjacent to the active region F-AA. The peripheral region F-NAA may have a given color. The peripheral region F-NAA may surround the active region F-AA. Accordingly, the shape of the active region F-AA may be substantially defined by the peripheral region F-NAA. However, this is illustrative, and the peripheral region F-NAA may be disposed adjacent to only one side or a side of the active region F-AA, or may be omitted. The display device ED may include active regions having various shapes and is not limited to any one embodiment.

A sensing region SA may be included in the active region F-AA. Various electronic modules may be disposed in the sensing region SA. For example, the electronic modules may include at least one of a camera module, a speaker, a light detection sensor, and a heat detection sensor. The sensing region SA may sense an external object received through the display surface FS, or may provide a sound signal, such as a voice, to the outside through the display surface FS. The electronic modules may include a plurality of components and are not limited to any one embodiment.

The sensing region SA may be surrounded by the active region F-AA and the peripheral region F-NAA. However, without being limited thereto, the sensing region SA may be disposed in the active region F-AA and is not limited to any one embodiment. Although one sensing region SA is illustrated in FIG. 1A, the number of sensing regions SA is not limited thereto.

The sensing region SA may be a portion of the active region F-AA. Accordingly, the display device ED may display an image through the sensing region SA. In case that the electronic modules disposed in the sensing region SA are deactivated, the sensing region SA may function as a display surface and may display a video or image.

A rear surface RS of the display device ED may be a surface facing the display surface FS. In an embodiment, the rear surface RS may be an outer surface of the display device ED, and a video or image may not be displayed on the rear surface RS. However, without being limited thereto, the rear surface RS may function as a second display surface on which a video or image is displayed. The display device ED may further include a sensing region disposed on the rear surface RS. A camera, a speaker, a light detection sensor, and the like may be disposed in the sensing region disposed on the rear surface RS.

The display device ED may include a folding region FA1 and non-folding regions NFA1 and NFA2. The display device ED may include a plurality of non-folding regions NFA1 and NFA2. The display device ED may include the first non-folding region NFA1 and the second non-folding region NFA2 disposed with the folding region FA1 therebetween. Although FIGS. 1A to IC illustrate an example that the display device ED may include one folding region FA1, embodiments are not limited thereto, and a plurality of folding regions may be defined in the display device ED. The display device ED may be folded about a plurality of folding axes such that portions of the display surface FS face each other, and the number of folding axes and the number of non-folding regions are not particularly limited.

Referring to FIGS. 1B and 1C, the display device ED may be folded about a first folding axis FX1. The first folding axis FX1 illustrated in FIGS. 1B and 1C may be a virtual axis extending in the first direction DR1. The first folding axis FX1 may be parallel to the direction of long sides of the display device ED. However, embodiments are not limited thereto, and the extension direction of the first folding axis FX1 is not limited to the first direction DR1.

The first folding axis FX1 may extend in the first direction DR1 above the display surface FS, or may extend in the first direction DR1 below the rear surface RS. Referring to FIG. 1B, in an embodiment, the display device ED may be folded in an in-folding manner such that the first non-folding region NFA1 and the second non-folding region NFA2 face each other and the display surface FS is not exposed to the outside. Furthermore, referring to FIG. 1C, in an embodiment, the display device ED may be folded about the first folding axis FX1 and may be changed to an out-folded state in which one region or a region of the rear surface RS that overlaps the first non-folding region NFA1 and an opposite region of the rear surface RS that overlaps the second non-folding region NFA2 face each other.

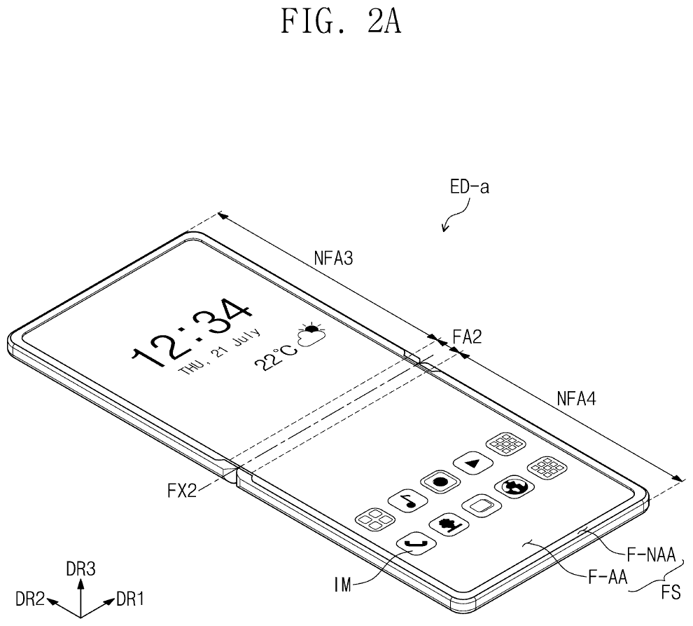

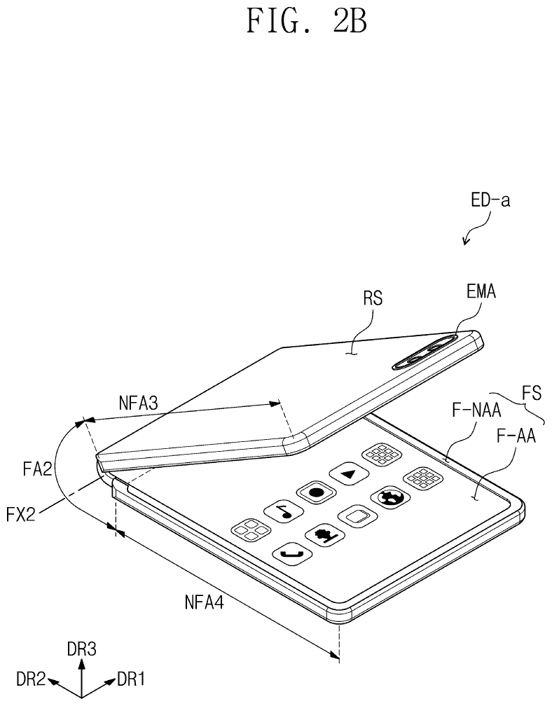

FIG. 2A is a schematic perspective view illustrating an unfolded state of a display device ED-a according to an embodiment. FIG. 2B is a schematic perspective view illustrating an in-folding process of the display device ED-a illustrated in FIG. 2A.

The display device ED-a may be folded about a second folding axis FX2 extending in one direction or a direction parallel to the first direction DR1. FIG. 2B illustrates an example that the extension direction of the second folding axis FX2 is parallel to the extension direction of short sides of the display device ED-a. However, embodiments are not limited thereto.

The display device ED-a may include at least one folding region FA2 and non-folding regions NFA3 and NFA4 adjacent to the folding region FA2. The non-folding regions NFA3 and NFA4 may be spaced apart from each other with the folding region FA2 therebetween.

The folding region FA2 has a given curvature and a given radius of curvature. In an embodiment, the display device ED-a may be folded in an in-folding manner such that the first non-folding region NFA3 and the second non-folding region NFA4 face each other and a display surface FS is not exposed to the outside.

In an embodiment, in an unfolded state of the display device ED-a, the display surface FS may be visible to a user, and in an in-folded state of the display device ED-a, a rear surface RS may be visible to the user. Unlike that illustrated in FIG. 2B, in an embodiment, the display device ED-a may be folded in an out-folding manner such that the display surface FS is exposed to the outside.

The display device ED-a may include the second display surface RS, and the second display surface RS may be defined as a surface opposite at least a portion of the first display surface FS. In the in-folded state, the second display surface RS may be visible to the user. The second display surface RS may include an electronic module region EMA in which electronic modules including various components are disposed. In an embodiment, an image may be provided through the second display surface RS.

In an embodiment, the display devices ED and ED-a may be configured such that an in-folding operation and an out-folding operation are repeatedly performed in an unfolded state. However, embodiments are not limited thereto. In an embodiment, the display devices ED and ED-a may be configured to select one of an unfolding operation, an in-folding operation, and an out-folding operation.

In FIGS. 1A to 2B, the display devices ED and ED-a are illustrated as foldable display devices that are able to be folded. However, embodiments are not limited thereto, and the display devices ED and ED-a may be flexible display devices that are able to be curved or rolled.

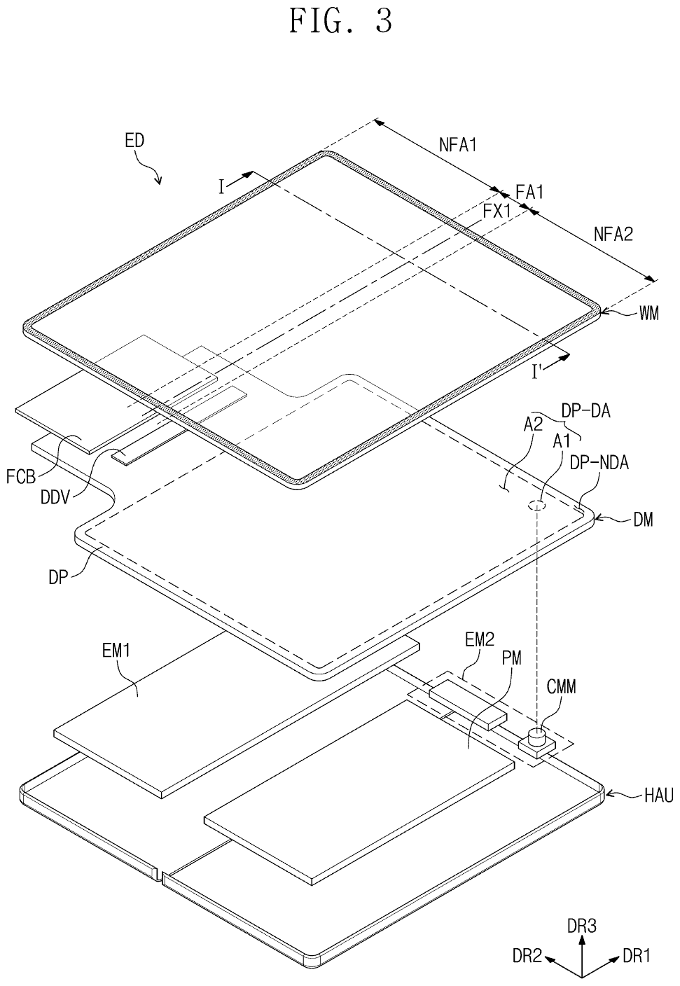

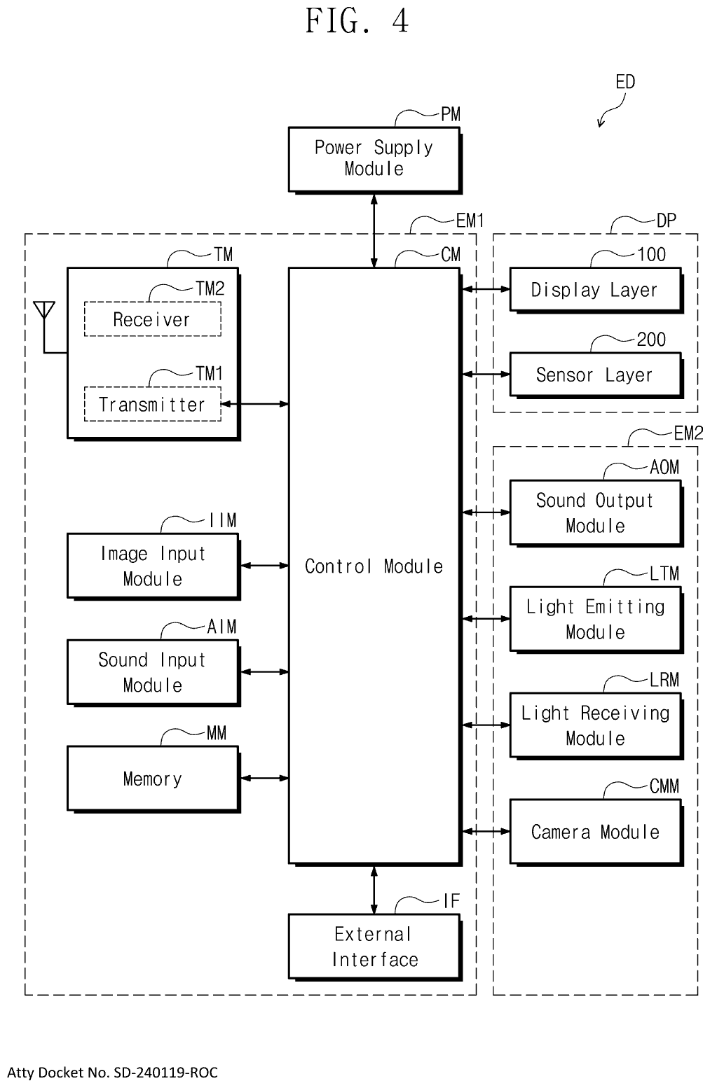

FIG. 3 is an exploded perspective view of the display device ED according to an embodiment. FIG. 4 is a block diagram of the display device ED according to an embodiment. Referring to FIGS. 3 and 4, the display device ED may include a window module WM, a display module DM, a first electronic module EM1, a second electronic module EM2, a power supply module PM, and a housing HAU. The display device ED may further include a mechanical structure for controlling a folding operation.

The window module WM may provide the front surface of the display device ED. The display module DM may include at least a display panel DP. The display module DM may generate an image and may sense an external input.

In FIG. 3, the display module DM is illustrated as being the same as the display panel DP. However, the display module DM may be a substantially stacked structure in which multiple components including the display panel DP are stacked each other. The stacked structure of the display module DM will be described below in detail.

The display panel DP may include a display region DP-DA and a non-display region DP-NDA that correspond to the active region F-AA (refer to FIG. 1A) and the peripheral region F-NAA (refer to FIG. 1A) of the display device ED, respectively. The expression “one region/portion corresponds to another region/portion” used herein means that the regions/portions overlap each other and is not limited to having the same area.

The display region DP-DA may include a first region A1 and a second region A2. The first region A1 may overlap, or correspond to, the sensing region SA (refer to FIG. 1A) of the display device ED. Although the first region A1 is illustrated in a circular shape in this embodiment, the first region A1 may have various shapes, such as a polygonal shape, an oval shape, a shape having at least one curved side, or an irregular shape, and is not limited to any one embodiment. The first region A1 may be referred to as a component region, and the second region A2 may be referred to as a main display region or a normal display region.

The first region A1 may have a higher transmittance than the second region A2. By way of example, the first region A1 may have a lower resolution than the second region A2. However, the disclosure is not limited thereto. For example, the first region A1 may have a higher transmittance than the second region A2, but may have substantially the same resolution as the second region A2. The first region A1 may overlap a camera module CMM that will be described below. In an embodiment, a portion of the display panel DP that corresponds to the first region A1 may be removed. Accordingly, an image may not be displayed on the first region A1.

The display panel DP may include a display layer 100 and a sensor layer 200.

The display layer 100 may be a component that substantially generates an image. The display layer 100 may be an emissive display layer. For example, the display layer 100 may be an organic light emitting display layer, an inorganic light emitting display layer, an organic-inorganic light emitting display layer, a quantum-dot display layer, a micro-LED display layer, or a nano-LED display layer.

The sensor layer 200 may be disposed on the display layer 100. The sensor layer 200 may sense an external input applied from the outside. The external input may be a user input. The user input may include various forms of external inputs such as a part of a user's body, light, heat, a pen, or pressure.

The display module DM may further include an anti-reflection layer (not illustrated) that is disposed on the sensor layer 200. The anti-reflection layer may be directly formed on the sensor layer 200 in case that the display module DM is manufactured. The anti-reflection layer may be defined as a film for preventing reflection of external light. The anti-reflection layer may decrease the reflectance of external light incident toward the display panel DP from above the display device ED. For example, the sensor layer 200 may be directly formed on the display layer 100, and the anti-reflection layer may be directly formed on the sensor layer 200. However, embodiments are not limited thereto. For example, the sensor layer 200 may be separately manufactured and attached to the display layer 100 by an adhesive layer, and the anti-reflection layer may be separately manufactured and attached to the sensor layer 200 by an adhesive layer.

The display module DM may include a data driver DDV disposed on the non-display region DP-NDA. The display module DM may further include a flexible circuit film FCB coupled (or connected) to the non-display region DP-NDA.

The data driver DDV may include drive elements (for example, a data drive circuit) for driving pixels of the display panel DP. Although FIG. 3 illustrates the structure in which the data driver DDV is mounted on the display panel DP, the disclosure is not limited thereto. For example, the data driver DDV may be mounted on the flexible circuit film FCB.

The power supply module PM may supply power required for overall operation of the display device ED. The power supply module PM may include a battery module.

The first electronic module EM1 and the second electronic module EM2 may include various functional modules for operating the display device ED. Each of the first electronic module EM1 and the second electronic module EM2 may be directly mounted on a mother board electrically connected with the display panel DP, or may be mounted on a separate substrate and electrically connected to the mother board through a connector (not illustrated).

The first electronic module EM1 may include a control module CM, a wireless communication module TM, an image input module IIM, a sound input module AIM, a memory MM, and an external interface IF.

The control module CM may control overall operation of the display device ED. The control module CM may be a microprocessor. For example, the control module CM activates or deactivates the display panel DP. The control module CM may control other modules, such as the image input module IIM or the sound input module AIM, based on a touch signal received from the display panel DP.

The wireless communication module TM may communicate with an external electronic device through a first network (for example, a short-range communication network such as Bluetooth, WiFi direct, or infrared data association (IrDA)) or a second network (for example, a long-range communication network such as a cellular network, Internet, or a computer network (for example, LAN or WAN)). Communication modules included in the wireless communication module TM may be integrated into one component (for example, a single chip), or may be implemented with a plurality of components (for example, a plurality of chips) separated from one another. The wireless communication module TM may transmit/receive sound signals using a general communication line. The wireless communication module TM may include a transmitter TM1 that modulates a signal to be transmitted and transmits the modulated signal and a receiver TM2 that demodulates a received signal.

The image input module IIM may process an image signal to convert the image signal into image data that is able to be displayed on the display panel DP. The sound input module AIM may receive an external sound signal through a microphone in a voice recording mode or a voice recognition mode and may convert the external sound signal into electrical voice data.

The external interface IF may include a connector capable of physically connecting the display device ED and an external electronic device. For example, the external interface IF may serve as an interface connected to an external charger, a wired/wireless data port, or a card (for example, memory card or SIM/UIM card) socket.

The second electronic module EM2 may include a sound output module AOM, a light emitting module LTM, a light receiving module LRM, and the camera module CMM. The sound output module AOM may convert sound data received from the wireless communication module TM or sound data stored in the memory MM and may output the converted data to the outside.

The light emitting module LTM may generate and output light. The light emitting module LTM may output infrared light. The light emitting module LTM may include an LED element. The light receiving module LRM may sense infrared light. The light receiving module LRM may be activated in case that infrared light above a given level is sensed. The light receiving module LRM may include a CMOS sensor. After infrared light generated by the light emitting module LTM is output, the infrared light may be reflected by an external object (for example, the user's finger or face), and the reflected infrared light may be incident to the light receiving module LRM.

The camera module CMM may take a still image and a video. The camera module CMM may include a plurality of camera modules. A part of the camera modules CMM may overlap the first region A1. An external input (for example, light) may be provided to the camera module CMM through the first region A1. For example, the camera module CMM may take an external image by receiving natural light through the first region A1.

The housing HAU may accommodate the display module DM, the first and second electronic modules EM1 and EM2, and the power supply module PM. The housing HAU may protect components accommodated in the housing HAU, such as the display module DM, the first and second electronic modules EM1 and EM2, and the power supply module PM. The housing HAU may be coupled (or connected) with the window module WM.

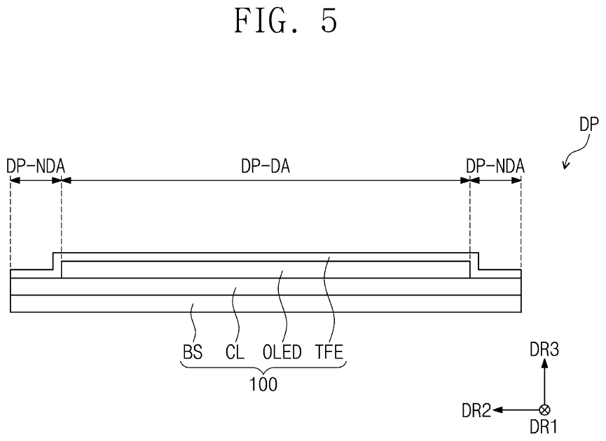

FIG. 5 is a sectional view of the display panel DP according to an embodiment.

FIG. 5 illustrates the display panel DP of FIGS. 3 and 4. In FIG. 5, the sensor layer 200 (refer to FIG. 4) is omitted, and the display layer 100 is illustrated.

Referring to FIG. 5, the display panel DP may include the display region DP-DA and the non-display region DP-NDA around the display region DP-DA. The display panel DP may include a base layer BS, a circuit layer CL, a light emitting element layer OLED, and an encapsulation layer TFE.

The base layer BS may provide a base surface on which the circuit layer CL is disposed. The base layer BS may be a flexible substrate that is able to be bent, folded, or rolled. The base layer BS may include a plastic substrate, a glass substrate, a metal substrate, or an organic/inorganic composite substrate. The base layer BS may have a multi-layer structure. For example, the base layer BS may include an inorganic layer, a synthetic resin layer, or a composite layer.

The circuit layer CL may be disposed on the base layer BS. The circuit layer CL may include at least one insulating layer, a semiconductor pattern, and a conductive pattern. The insulating layer, the semiconductor pattern, and the conductive pattern of the circuit layer CL may be formed by forming an insulating layer, a semiconductor layer, and a conductive layer through coating or deposition and thereafter making the insulating layer, the semiconductor layer, and the conductive layer subject to patterning by performing a photolithography process a plurality of times. The insulating layer, the semiconductor pattern, and the conductive pattern included in the circuit layer CL may form drive elements (for example, transistors), signal lines, and pads in the circuit layer CL.

The light emitting element layer OLED may be disposed on the circuit layer CL. The light emitting element layer OLED may include light emitting elements. The light emitting elements of the light emitting element layer OLED may be electrically connected to the drive elements of the circuit layer CL and may display an image by generating light depending on signals provided by the drive elements.

The encapsulation layer TFE may be disposed on the light emitting element layer OLED and may seal the light emitting elements. The encapsulation layer TFE may include at least one thin film for improving the optical efficiency of the light emitting element layer OLED or protecting the light emitting element layer OLED. The encapsulation layer TFE may protect the light emitting element layer OLED from moisture, oxygen, and external foreign matter.

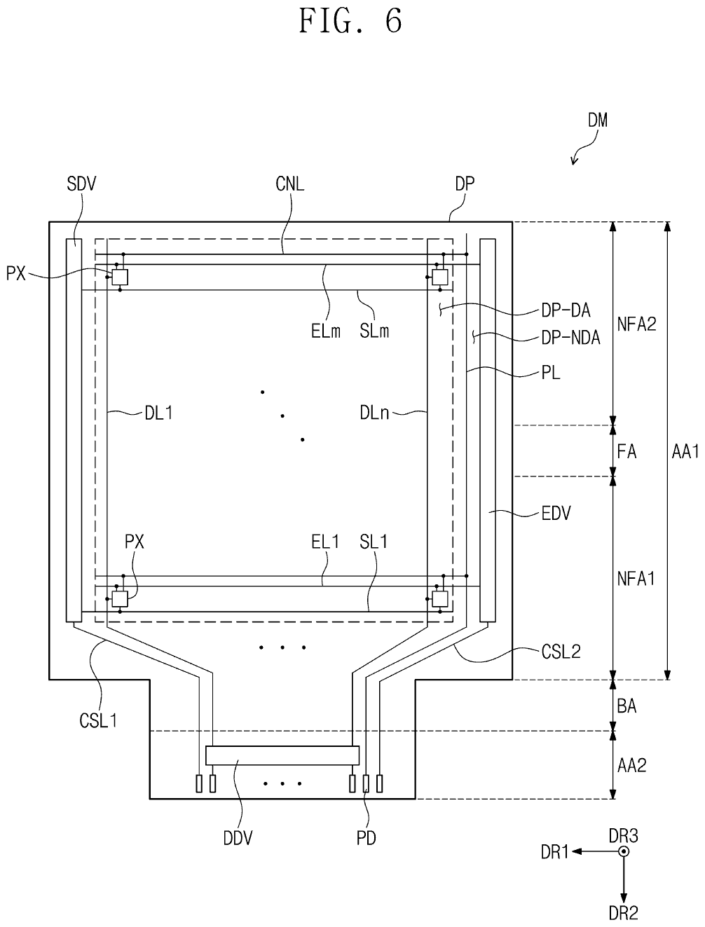

FIG. 6 is a sectional view of the display module DM according to an embodiment.

Referring to FIG. 6, the display module DM may include the display panel DP, a scan driver SDV, the data driver DDV, and an emission driver EDV.

The display panel DP may include a first region AA1, a second region AA2, and a bending region BA between the first region AA1 and the second region AA2. The bending region BA may extend in the first direction DR1, and the first region AA1, the bending region BA, and the second region AA2 may be arranged in the second direction DR2.

The first region AA1 may include a display region DP-DA and a non-display region DP-NDA around the display region DP-DA. The non-display region DP-NDA may surround the display region DP-DA. The display region DP-DA may be a region that displays an image, and the non-display region DP-NDA may be a region that does not display an image. The second region AA2 and the bending region BA may be regions that do not display an image.

The first region AA1, when viewed in the first direction DR1, may include a first non-folding region NFA1, a second non-folding region NFA2, and a folding region FA between the first non-folding region NFA1 and the second non-folding region NFA2.

The display panel DP may include a plurality of pixels PX, a plurality of scan lines SL1 to SLm, a plurality of data lines DLI to DLn, a plurality of emission lines ELI to ELm, first and second control lines CSL1 and CSL2, a power line PL, a plurality of connecting lines CNL, and a plurality of pads PD. Here, “m” and “n” are natural numbers. The pixels PX may be disposed in the display region DP-DA and may be connected to the scan lines SL1 to SLm, the data lines DLI to DLn, and the emission lines ELI to ELm.

The scan driver SDV and the emission driver EDV may be disposed in the non-display region DP-NDA. The scan driver SDV and the emission driver EDV may be disposed in the non-display regions DP-NDA adjacent to opposite sides of the first region AA1 that face away from each other in the first direction DR1. The data driver DDV may be disposed in the second region AA2. The data driver DDV may be manufactured in the form of an integrated circuit chip and may be mounted on the second region AA2.

The scan lines SL1 to SLm may extend in the first direction DR1 and may be connected to the scan driver SDV. The data lines DLI to DLn may extend in the second direction DR2 and may be connected to the data driver DDV via the bending region BA. The emission lines ELI to ELm may extend in the first direction DR1 and may be connected to the emission driver EDV.

The power line PL may extend in the second direction DR2 and may be disposed in the non-display region DP-NDA. The power line PL may be disposed between the display region DP-DA and the emission driver EDV. However, without being limited thereto, the power line PL may be disposed between the display region DP-DA and the scan driver SDV.

The power line PL may extend to the second region AA2 via the bending region BA. The power line PL may extend toward a lower end of the second region AA2 when viewed from above the plane. The power line PL may receive a drive voltage.

The connecting lines CNL may extend in the first direction DR1 and may be arranged in the second direction DR2. The connecting lines CNL may be connected to the power line PL and the pixels PX. The drive voltage may be applied to the pixels PX through the power line PL and the connecting lines CNL connected with each other.

The first control line CSL1 may be connected to the scan driver SDV and may extend toward the lower end of the second region AA2 via the bending region BA. The second control line CSL2 may be connected to the emission driver EDV and may extend toward the lower end of the second region AA2 via the bending region BA. The data driver DDV may be disposed between the first control line CSL1 and the second control line CSL2.

The pads PD may be disposed adjacent to the lower end of the second region AA2 when viewed from above the plane. The data driver DDV, the power line PL, the first control line CSL1, and the second control line CSL2 may be connected to the pads PD.

The data lines DLI to DLn may be connected to the corresponding pads PD through the data driver DDV. For example, the data lines DLI to DLn may be connected to the data driver DDV, and the data driver DDV may be connected to the pads PD corresponding to the data lines DLI to DLn.

Although not illustrated, a printed circuit board may be connected to the pads PD, and a timing controller and a voltage generator may be disposed on the printed circuit board. The timing controller may be manufactured in the form of an integrated circuit chip and may be mounted on the printed circuit board. The timing controller and the voltage generator may be connected to the pads PD through the printed circuit board.

The timing controller may control operations of the scan driver SDV, the data driver DDV, and the emission driver EDV. The timing controller may generate a scan control signal, a data control signal, and an emission control signal in response to control signals received from the outside. The voltage generator may generate the drive voltage.

The scan control signal may be provided to the scan driver SDV through the first control line CSL1. The emission control signal may be provided to the emission driver EDV through the second control line CSL2. The data control signal may be provided to the data driver DDV. The timing controller may receive image signals from the outside, may convert the data format of the image signals according to the specification of an interface with the data driver DDV, and may provide the converted signals to the data driver DDV.

The scan driver SDV may generate a plurality of scan signals in response to the scan control signal. The scan signals may be applied to the pixels PX through the scan lines SL1 to SLm. The scan signals may be sequentially applied to the pixels PX.

The data driver DDV may generate a plurality of data voltages corresponding to the image signals in response to the data control signal. The data voltages may be applied to the pixels PX through the data lines DLI to DLn. The emission driver EDV may generate a plurality of emission signals in response to the emission control signal. The emission signals may be applied to the pixels PX through the emission lines ELI to ELm.

The pixels PX may receive the data voltages in response to the scan signals. The pixels PX may display an image by emitting light having luminance corresponding to the data voltages in response to the emission signals. The light emission time of the pixels PX may be controlled by the emission signals.

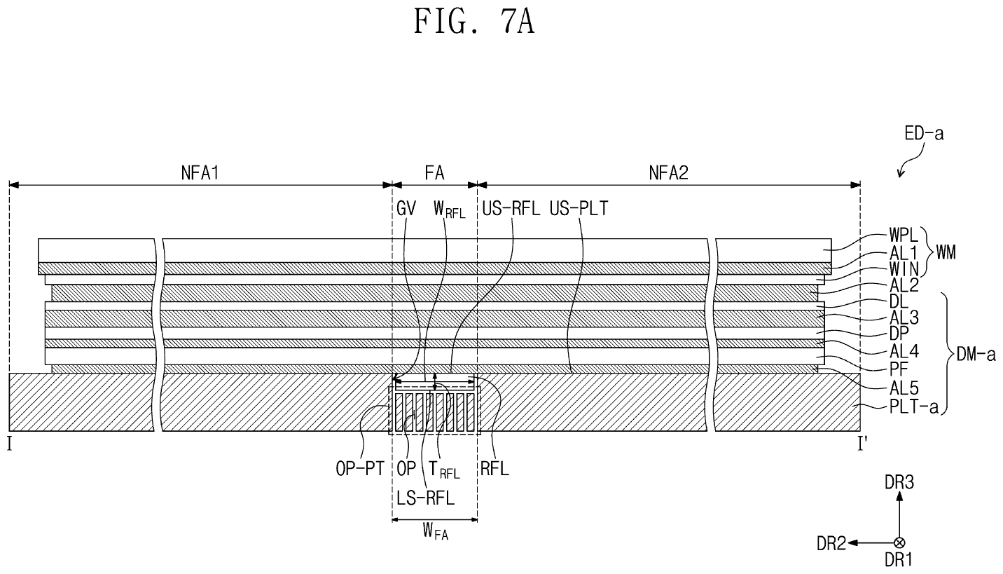

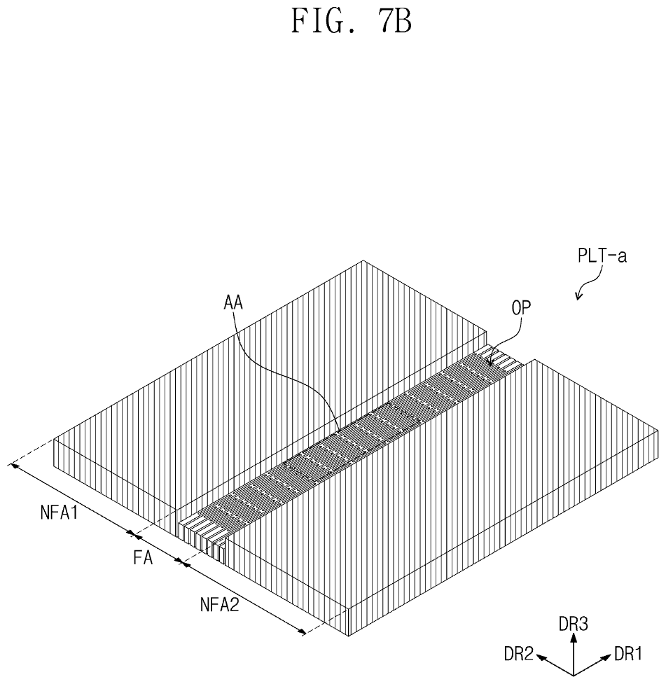

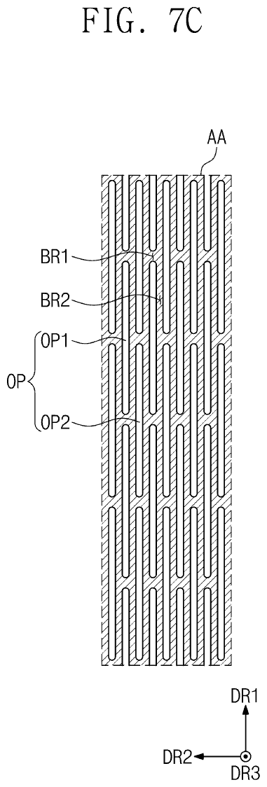

FIG. 7A is a sectional view of the display device ED-a according to an embodiment. FIG. 7B is a schematic perspective view of a support plate PLT-a according to an embodiment. FIG. 7C is an enlarged plan view of a portion of the support plate PLT-a according to an embodiment.

FIG. 7A illustrates an embodiment of a cut section of the display device ED corresponding to line I-I′ of FIG. 3. FIG. 7B illustrates a schematic perspective view of the support plate PLT-a of FIG. 7A. FIG. 7C is an enlarged plan view of region AA of FIG. 7B.

Referring to FIG. 7A, the display device ED-a may include a window module WM and a display module DM-a. The display device ED-a may include adhesive layers AL1, AL2, AL3, AL4, and AL5 between the window module WM and the display module DM-a and between a plurality of layers included in the window module WM or the display module DM-a. The adhesive layers AL1, AL2, AL3, AL4, and AL5 may be omitted.

The adhesive layers AL1, AL2, AL3, AL4, and AL5 may include one of an optical clear adhesive (OCA), an optical clear resin (OCR), and a pressure sensitive adhesive (PSA).

The window module WM may be disposed on the display module DM-a. The window module WM may alleviate external impact while transmitting an image from the display module DM-a. Accordingly, the window module WM may prevent damage or malfunction of the display module DM-a due to the external impact.

The window module WM may include a window WIN, a window protection layer WPL disposed over the window WIN, and the adhesive layer AL1 disposed between the window WIN and the window protection layer WPL. The window protection layer WPL or the adhesive layer AL1 may be omitted.

The window WIN may be disposed on the display module DM-a. The window WIN may protect the display module DM-a from external scratches. The window WIN may have a property of being optically clear. The window WIN may include glass. However, without being limited thereto, the window WIN may include a synthetic resin film. The window WIN may have a multi-layer structure or a single-layer structure. For example, the window WIN may include a plurality of synthetic resin films coupled (or connected) by an adhesive, or may include a glass substrate and a synthetic resin film coupled (or connected) by an adhesive.

The window protection layer WPL may be disposed on the window WIN. The window protection layer WPL may include a flexible plastic material such as polyimide or polyethylene terephthalate. A hard coating layer (not illustrated) may be disposed on the window protection layer WPL.

The window module WM may include a functional layer including at least one of the hard coating layer (not illustrated) and an anti-fingerprint layer (not illustrated) that are disposed on the window protection layer WPL. By way of example, the window module WM may include a functional layer that simultaneously functions as the hard coating layer and the anti-fingerprint layer. The hard coating layer may be a layer for providing physical strength to the window module WM. The anti-fingerprint layer may be a layer that prevents external contamination such as fingerprints and suppresses wear due to external friction. Each of the functional layers may further include an anti-reflection function or an anti-glare function.

The display module DM-a may include a display panel DP. The display module DM-a may include an impact absorbing layer DL disposed on the display panel DP. The display module DM-a may include a panel protection layer PF and the support plate PLT-a that are disposed under (or below) the display panel DP, and the support plate PLT-a may have a groove GV defined thereon. The display module DM-a may include an impact resistance enhancement layer RFL disposed in the groove GV of the support plate PLT-a.

The contents described above with reference to FIGS. 1A to 6 may be identically applied to the display panel DP.

The impact absorbing layer DL may be disposed on the display panel DP. The impact absorbing layer DL may protect the display panel DP by absorbing external impact applied toward the display panel DP from above the display device ED-a. The impact absorbing layer DL may be manufactured in the form of a stretchable film. The impact absorbing layer DL may include a flexible plastic material. The flexible plastic material may be defined as a synthetic resin film. For example, the impact absorbing layer DL may include a flexible plastic material such as polyimide (PI) or polyethylene terephthalate (PET). The impact absorbing layer DL may be coupled (or connected) with the display panel DP by the adhesive layer AL3.

The panel protection layer PF may be disposed under the display panel DP. The panel protection layer PF disposed under the display panel DP may protect a lower portion of the display panel DP. The panel protection layer PF may include a flexible plastic material. For example, the panel protection layer PF may include polyethylene terephthalate (PET). The panel protection layer PF may be coupled (or connected) with the display panel DP by the adhesive layer AL4.

The support plate PLT-a may be disposed under the display panel DP. The support plate PLT-a may be disposed under the panel protection layer PF. The support plate PLT-a may be coupled (or connected) with the panel protection layer PF by the adhesive layer AL5. The support plate PLT-a disposed under the display panel DP may support the display panel DP.

The support plate PLT-a may include a material having a high modulus. The support plate PLT-a may include a metallic material or a polymer material. For example, the support plate PLT-a may include stainless steel, aluminum, or an alloy thereof. By way of example, the support plate PLT-a may include carbon fiber reinforced plastic (CFRP). However, embodiments are not limited thereto, and the support plate PLT-a may include a non-metallic material, plastic, glass fiber reinforced plastic, or glass.

The support plate PLT-a may have a plurality of openings OP defined therein. The support plate PLT-a may include an opening pattern OP-PT including the plurality of openings OP. The opening pattern OP-PT may correspond to the folding region FA when viewed from above the plane. The plurality of openings OP and the opening pattern OP-PT will be described below in detail with reference to FIGS. 7B and 7C.

The support plate PLT-a may include an upper surface US-PLT adjacent to the display panel DP. The groove GV may be defined on the upper surface US-PLT of the support plate PLT-a. The groove GV may be referred to as a recess. The groove GV may be formed through an etching process.

As the groove GV is defined on the upper surface US-PLT of the support plate PLT-a, the impact resistance enhancement layer RFL to be described below may be disposed in the groove GV. Accordingly, the impact resistance enhancement layer RFL may sufficiently support and protect the display panel DP against external impact applied to the folding region FA from the display surface FS (refer to FIG. 1A) of the display device ED-a.

The groove GV may correspond to the folding region FA when viewed from above the plane. For example, the length of the groove GV in the second direction DR2 may be equal to the length (width) W_{FA} of the folding region FA in the second direction DR2. Here, based on the second direction DR2, the width W_{FA} of the folding region FA may refer to the length of the region of the support plate PTL-a where the opening pattern OP-PT is disposed.

Without being limited thereto, the groove GV may overlap not only the folding region FA but also portions of the non-folding regions NFA1 and NFA2. For example, the length of the groove GV in the second direction DR2 may be greater than the width W_{FA} of the folding region FA.

The impact resistance enhancement layer RFL may be disposed in the groove GV of the support plate PLT-a. The shape of the impact resistance enhancement layer RFL may correspond to the shape of the groove GV of the support plate PLT-a.

The impact resistance enhancement layer RFL may correspond to the folding region FA when viewed from above the plane. For example, the width W_{RFL} of the impact resistance enhancement layer RFL may be equal to the width W_{FA} of the folding region FA. Here, the width W_{RFL} of the impact resistance enhancement layer RFL may refer to the length in the second direction DR2.

Without being limited thereto, the impact resistance enhancement layer RFL may overlap not only the folding region FA but also portions of the non-folding regions NFA1 and NFA2. For example, the width W_{RFL} of the impact resistance enhancement layer RFL may be greater than the width W_{FA} of the folding region FA. For example, the width W_{RFL} of the impact resistance enhancement layer RFL may be greater than the width W_{FA} of the folding region FA by 2 mm to 4 mm.

The impact resistance enhancement layer RFL may be coupled (or connected) with the panel protection layer PF by the adhesive layer AL5. The impact resistance enhancement layer RFL may include an upper surface US-RFL adjacent to the panel protection layer PF and a lower surface LS-RFL adjacent to the opening pattern OP-PT of the support plate PLT-a. The upper surface US-RFL of the impact resistance enhancement layer RFL may be disposed directly under the adhesive layer AL5 and may be coupled (or connected) with the panel protection layer PF. The adhesive layer AL5 disposed between the panel protection layer PF and the impact resistance enhancement layer RFL may be referred to as the first adhesive layer.

The impact resistance enhancement layer RFL may have a thickness T_{RFL} in a range of about 30 μm to about 50 μm. In case that the thickness T_{RFL} of the impact resistance enhancement layer RFL is less than 30 μm, the impact resistance of the folding region FA is very low. As the thickness TRH, of the impact resistance enhancement layer RFL is increased, the impact resistance of the folding region FA may be raised. However, in case that the thickness T_{RFL} of the impact resistance enhancement layer RFL exceeds about 50 μm, the impact resistance of the folding region FA may be saturated. Furthermore, in case that the thickness T_{RFL} of the impact resistance enhancement layer RFL is increased, a crack may occur due to stress during folding, which may lead to a folding defect.

The impact resistance enhancement layer RFL may have a modulus in a range of about 3 GPa to about 6 GPa. In case that the modulus of the impact resistance enhancement layer RFL is less than about 3 GPa, the impact resistance of the folding region FA is very low. As the modulus of the impact resistance enhancement layer RFL is increased, the impact resistance of the folding region FA may be raised. However, in case that the modulus of the impact resistance enhancement layer RFL exceeds about 6GP, the impact resistance of the folding region FA may be saturated. Furthermore, in case that the modulus of the impact resistance enhancement layer RFL is increased, a crack may occur due to stress during folding, which may lead to a folding defect.

The impact resistance enhancement layer RFL may include a polymer material. For example, the impact resistance enhancement layer RFL may include polyimide or PET. However, without being limited thereto, the impact resistance enhancement layer RFL may include a material having the aforementioned modulus irrespective of the type thereof. The impact resistance enhancement layer RFL may have a color. For example, the impact resistance enhancement layer RFL may be black in color.

The display device ED-a according to the disclosure may include the opening pattern OP-PT defined in the support plate PLT-a and thus may be readily folded. Furthermore, the display device ED-a may include the groove GV defined on the upper surface US-PLT of the support plate PLT-a and the impact resistance enhancement layer RFL disposed in the groove GV, and thus the impact resistance of the folding region FA may be improved.

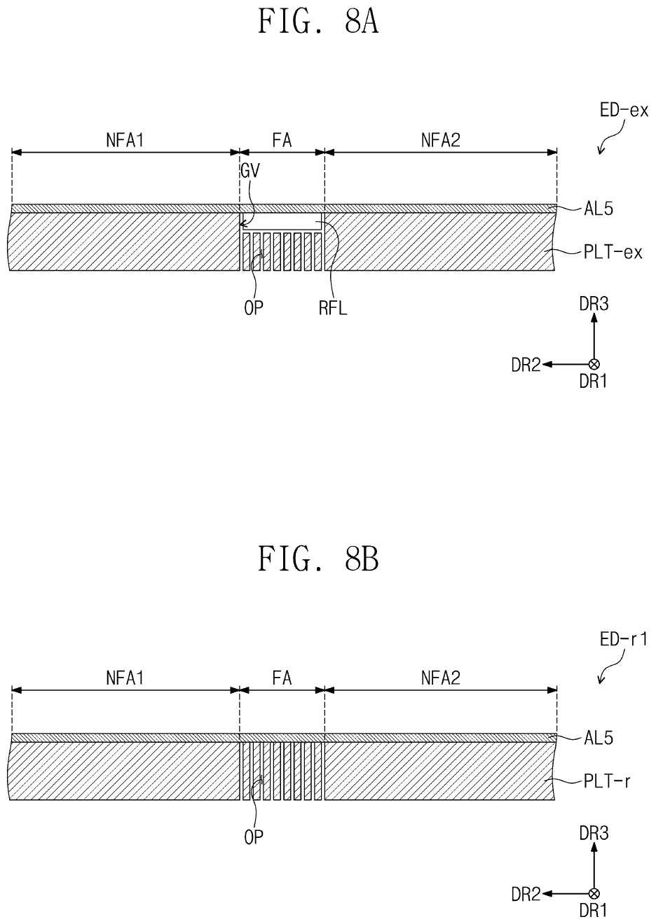

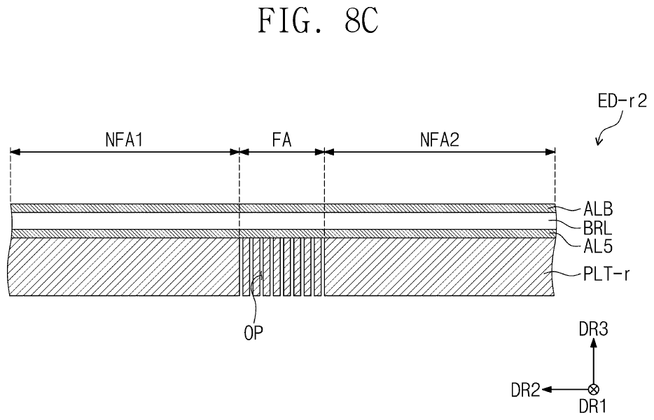

By eliminating an increase in thickness caused by a barrier layer BRL (refer to FIG. 8C) and an adhesive layer for coupling (or connecting) the barrier layer BRL (refer to FIG. 8C), the display device ED-a may have a small thickness, as compared with in case that the barrier layer BRL (refer to FIG. 8C) for supplementing the impact resistance of the folding region FA is separately provided between the support plate PLT-a and the panel protection layer PF. Furthermore, as compared with in case that the barrier layer BRL (refer to FIG. 8C) is included, the bending stiffness may be improved, and the unit cost may be reduced.

The display device ED-a may further include a lower member (not illustrated) that is disposed under the support plate PLT-a. For example, the lower member may include at least one of a support layer, a cushion layer, and a shielding layer. The configuration of the lower member may vary depending on the size, shape, or operating characteristics of the display device ED-a. The lower member may further include a digitizer.

The support layer may include a metallic material or a polymer material. The support layer may be disposed under the support plate PLT-a and may support the layers disposed on the support layer. For example, the support layer may be a thin metal substrate.

The cushion layer may be disposed under the support layer. The cushion layer may prevent the support plate PLT-a from being pressed and plastically deformed by external impact and force. Accordingly, the cushion layer may further improve the impact resistance of the display device ED-a. The cushion layer may include an elastomer such as a sponge, expanded foam, or a urethane resin. Furthermore, the cushion layer may include at least one of an acrylic polymer, a urethane-based polymer, a silicon-based polymer, and an imide-based polymer. However, embodiments are not limited thereto.

The shielding layer may be disposed under the cushion layer. The shielding layer may be an EM1 shielding layer or a heat radiating layer.

Referring to FIG. 7B, the support plate PLT-a may include the plurality of openings OP in the folding region FA. The plurality of openings OP may be referred to as the plurality of holes. The plurality of openings OP may be formed through the support plate PLT-a in the third direction DR3. The plurality of openings OP may be formed through a laser process or a micro-blast process.

The plurality of openings OP may be arranged according to a selectable rule. The plurality of openings OP may be arranged in a lattice form and may form a lattice pattern in the folding region FA.

As the plurality of openings OP are defined, the area of the support plate PLT-a that corresponds to the folding region FA may be reduced, and therefore the rigidity of the support plate PLT-a that corresponds to the folding region FA may be lowered. Accordingly, in case that the plurality of openings OP are defined, the flexibility of the support plate PLT-a corresponding to the folding region FA may be increased, as compared with in case that the plurality of openings OP are not defined in the support plate PLT-a. Thus, the support plate PLT-a may be readily folded.

Referring to FIG. 7C, the plurality of openings OP may include a plurality of first openings OP1 and a plurality of second openings OP2. The plurality of first openings OP1 and the plurality of second openings OP2 may be referred to as the plurality of first holes OP1 and the plurality of second holes OP2, respectively.

The plurality of first openings OP1 may be arranged in the first direction DR1. The plurality of second openings OP2 may be arranged in the first direction DR1. The first openings OP1 and the second openings OP2 may be alternately arranged in the second direction DR2. The first openings OP1 and the second openings OP2 may be staggered with respect to each other in the first direction DR1.

The support plate PLT-a corresponding to the folding region FA may include first branch portions BR1 disposed between the first openings OP1 or the second openings OP2. The first branch portions BR1 may be disposed between the first openings OP1 adjacent to each other in the first direction DR1 or the second openings OP2 adjacent to each other in the first direction DR1.

The support plate PLT-a corresponding to the folding region FA may include second branch portions BR2 disposed between the first openings OP1 and the second openings OP2. The second branch portions BR2 may be disposed between the first openings OP1 and the second openings OP3 adjacent to each other in the second direction DR2.

FIG. 8A is a sectional view illustrating a portion of a display device ED-ex according to an embodiment. FIGS. 8B and 8C are sectional views illustrating portions of display devices ED-r1 and ED-r2 according to comparative examples.

FIGS. 8A to 8C illustrate stacked structures for evaluation of the impact resistance characteristics of the display devices ED-ex, ED-r1, and ED-r2. FIG. 8A is referred to as embodiment 1, FIG. 8B is referred to as comparative example 1, and FIG. 8C is referred to as comparative example 2.

The display device ED-ex of embodiment 1 may include a cushion layer (about 200 μm), a support plate (about 150 μm), an adhesive layer (about 25 μm), a panel protection layer (about 50 μm), an adhesive layer (about 25 μm), a display panel (about 30 μm), an adhesive layer (about 25 μm), an impact absorbing layer (about 50 μm), an adhesive layer (about 25 μm), a window (about 30 μm), an adhesive layer (about 50 μm), a window protection layer (about 65 μm), and a hard coating layer (about 5 μm). A groove GV is defined on an upper surface US-PLT of the support plate PLT-ex, and an impact resistance enhancement layer RFL (about 50 μm) is disposed in the groove GV. In FIG. 8A, only the support plate PLT-ex, the adhesive layer AL5, and the impact resistance enhancement layer RFL are illustrated.

The display device ED-r1 of comparative example 1 has the same stacked structure as the display device ED-ex of embodiment 1, except that the groove GV is not defined on a support plate PLT-r and the display device ED-r1 does not include the impact resistance enhancement layer RFL. In FIG. 8B, only the support plate PLT-r and an adhesive layer AL5 are illustrated.

The display device ED-r2 of comparative example 2 has the same stacked structure as the display device ED-ex of embodiment 1, except that the groove GV is not defined on a support plate PLT-r and the display device ED-r2 does not include the impact resistance enhancement layer RFL and further may include the barrier layer BRL and a barrier adhesive layer ALB. The barrier layer BRL may be disposed under a panel protection layer in a folding region FA and non-folding regions NFA1 and NFA2 and may serve to protect a display panel from external impact. The barrier layer BRL may include a flexible plastic material such as polyimide or polyethylene terephthalate. In FIG. 8C, only the support plate PLT-r, an adhesive layer AL5, the barrier layer BRL, and the barrier adhesive layer ALB are illustrated.

Table 1 shows results obtained by evaluating the impact resistance characteristics of the display devices ED-ex, ED-r1, and Ed-r2 of embodiment 1, comparative example 1, and comparative example 2. By way of example, the pen drop test was performed on the folding region FA and the non-folding regions NFA1 and NFA2 to measure the heights at which the defects occurred. In the pen drop test, the pen having 0.3π and 5.8 g was applied.

TABLE 1

| | | Comparative | Comparative |
|---|---|---|---|
| | Embodiment 1 | example 1 | example 2 |
| Height (cm) at which | 8 | 2.6 | 7.3 |
| defect occurs in | | | |
| folding region | | | |
| Height (cm) at which | 15.7 | 15.4 | 14 |
| defect occurs in | | | |
| non-folding region | | | |

Referring to Table 1, the display device ED-ex of embodiment 1 has higher impact resistance characteristics in both the folding region FA and the non-folding regions NFA1 and NFA2 than the display devices ED-r1 and ED-r2 of comparative examples 1 and 2. By way of example, as the display device ED-ex of embodiment 1 may include the impact resistance enhancement layer RFL in the folding region FA, the impact resistance characteristics in the folding region FA are improved.

In contrast, as the opening pattern OP-PT exists in the folding region FA of the display device ED-r1 of comparative example 1, the impact resistance characteristics of the folding region FA are low. The display device ED-r2 of comparative example 2 may include the barrier layer BRL and thus ensures impact resistance characteristics. However, the thickness of the display device ED-r2 is increased due to the barrier layer BRL and the barrier adhesive layer ALB.

Table 2 shows conditions for evaluation of the impact resistance characteristics of display devices according to embodiments A to C and comparative examples A to C and evaluation results. The pen drop test was performed in the same manner as described above with reference to FIGS. 8A to 8C.

Table 3 shows results obtained by evaluating strains for folding reliability of impact resistance enhancement layers of the display devices according to embodiments A to C and comparative examples A to C. The 1.4R in-folding evaluation was performed on the outer surfaces (the surfaces adjacent to support plates) and the inner surfaces (the surfaces adjacent to panel protective layers) of the impact resistance enhancement layers.

The display devices of embodiments A to C and comparative examples A to C have the same structure as the display device of embodiment 1 described above with reference to FIG. 8A. However, the impact resistance enhancement layers have different moduli and/or thicknesses as shown in Table 2.

TABLE 2

| | Modulus (GPa) | Thickness (μm) | Height (cm) |
|---|---|---|---|
| | of impact | of impact | at which |
| | resistance | resistance | defect occurs |
| | enhancement | enhancement | in folding |
| | layer | layer | region |
| Embodiment A | 3.3 | 50 | 8 |
| Embodiment B | 3.3 | 35 | 6 |
| Embodiment C | 6 | 50 | 9 |
| Comparative | 0.74 | 50 | 5 |
| example A | | | |
| Comparative | 3.3 | 75 | 8 |
| example B | | | |
| Comparative | 70 | 50 | 9 |
| example C | | | |

TABLE 3

| | Strain (%) of | Strain (%) of |
|---|---|---|
| | outer surface | inner surface |
| | of impact | of impact |
| | resistance | resistance |
| | enhancement | enhancement |
| | layer | layer |
| Embodiment A | 2.84 | −0.41 |
| Embodiment B | 2.56 | 0.27 |
| Embodiment C | 2.26 | −1.00 |
| Comparative | 3.61 | 0.95 |
| example A | | |
| Comparative | Occurrence | Occurrence |
| example B | of crack | of crack |
| Comparative | Occurrence | Occurrence |
| example C | of crack | of crack |

Referring to Table 2, when embodiments A and C and comparative example A, in which the impact resistance enhancement layers have the same thickness, are compared with one another, the display device of comparative example A that includes the impact resistance enhancement layer having the low modulus have very low impact resistance characteristics.

When embodiments A and C and comparative example C, in which the impact resistance enhancement layers have the same thickness, are compared with one another, it can be seen that the heights at which defects occur in the folding regions are saturated in case that the modulus exceeds about 6 GPa. For example, the impact resistance characteristics are saturated. In the case of the impact resistance enhancement layer of comparative example C that has the high modulus, a crack occurs during folding as shown in Table 3.

In the case of the display device of embodiment C, the height at which the defect occurs in the folding region is greater than that in the case of the display device of embodiment A. For example, it can be seen that in case that the impact resistance enhancement layers have the same thickness, the display device including the impact resistance enhancement layer having the higher modulus has better impact resistance characteristics up to about 6 GPa.

Referring to Table 2, when embodiments A and B and comparative example B, in which the impact resistance enhancement layers have the same modulus, are compared with one another, it can be seen that the heights at which the defects occur in the folding regions are saturated in case that the thicknesses of the impact resistance enhancement layers exceed about 50 μm. For example, the impact resistance characteristics are saturated. In the case of the impact resistance enhancement layer of comparative example B that has a large thickness, a crack occurs during folding as shown in Table 3.

Table 4 shows results obtained by evaluating the folding reliability of the display device of embodiment A in various environments.

TABLE 4

| | | Number of folding | |
|---|---|---|---|
| | | operations | |
| | Environment | (times) | Reliability |
| Embodiment A-1 | Room temperature | 200,000 | Pass |
| | (25° C.) | | |
| Embodiment A-2 | High temperature/ | 70,000 | Pass |
| | High humidity | | |
| | (60° C./93%) | | |
| Embodiment A-3 | Low temperature | 30,000 | Pass |
| | (−20° C.) | | |

Referring to Table 4, it can be seen that the display device according to embodiment A of the disclosure not only has excellent impact resistance characteristics, but also has excellent folding reliability in various environments.

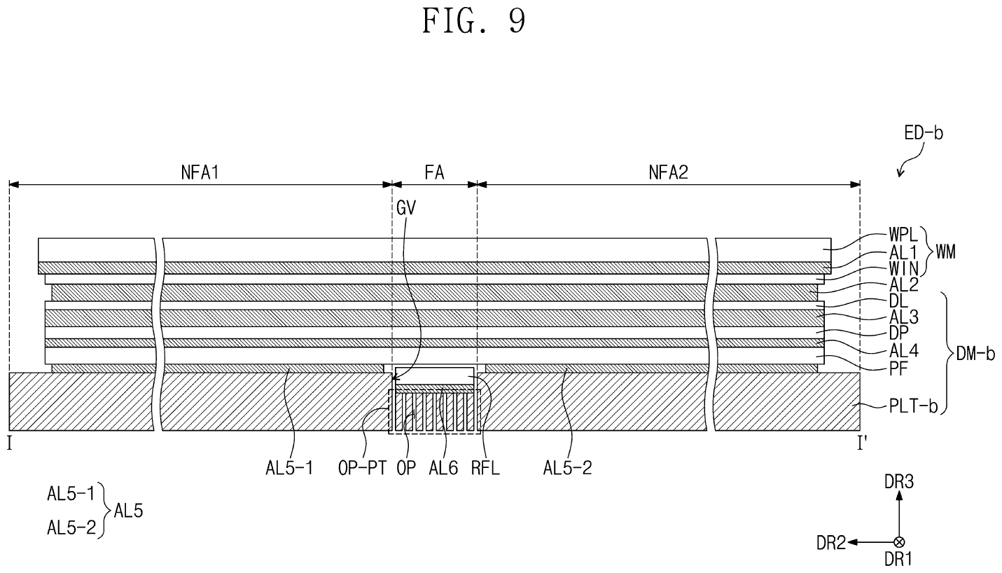

FIG. 9 is a sectional view of a display device ED-b according to an embodiment. FIG. 9 illustrates an embodiment of the cut section of the display device ED corresponding to line I-I′ of FIG. 3.

In case that compared to the display device ED-a of FIG. 7A, the display device ED-b of FIG. 9 may further include an adhesive layer AL6 disposed between an impact resistance enhancement layer RFL and an opening pattern OP-PT of a support plate PLT-b. The adhesive layer AL6 disposed between the impact resistance enhancement layer RFL and the opening pattern OP-PT of the support plate PLT-b may be referred to as the second adhesive layer. The contents regarding the above-described adhesive layers AL1, AL2, AL3, ALA, and AL5 may be identically applied to the material of the second adhesive layer AL6. The impact resistance enhancement layer RFL may be coupled (or connected) to the support plate PLT-b through the second adhesive layer AL6. By way of example, the impact resistance enhancement layer RFL may be coupled (or connected) to the opening pattern OP-PT of the support plate PLT-b. For example, the adhesive layer AL6 may have a thickness in a range of about 15 μm to about 25 μm. The display module DM-b may include an impact absorbing layer DL, adhesive layers AL3 and AL4, display panel DP, panel protection layer PF and support plate PLT-b.

In case that compared to the adhesive layer AL5 of the display device ED-a of FIG. 7A, a first adhesive layer AL5 of the display device ED-b of FIG. 9 may include an adhesive layer 1-1 AL5-1 and an adhesive layer 1-2 AL5-2 spaced apart from each other. The adhesive layer 1-1 AL5-1 may be disposed to correspond to a first non-folding region NFA1, and the adhesive layer 1-2 AL5-2 may be disposed to correspond to a second non-folding region NFA2. The adhesive layer 1-1 AL5-1 and the adhesive layer 1-2 AL5-2 may not overlap a folding region FA. The impact resistance enhancement layer RFL may be disposed between the adhesive layer 1-1 AL5-1 and the adhesive layer 1-2 AL5-2.

In addition to those described above, the same contents as the display device ED-a of FIG. 7A may be applied to the display device ED-b of FIG. 9.

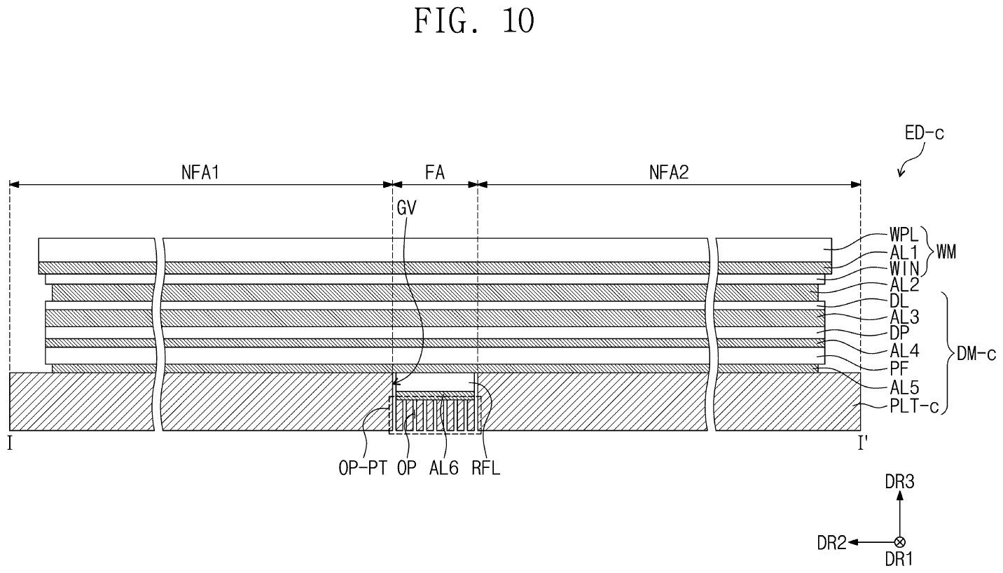

FIG. 10 is a sectional view of a display device ED-c according to an embodiment. FIG. 10 illustrates an embodiment of the cut section of the display device ED corresponding to line I-I′ of FIG. 3.

Similar to the display device ED-b of FIG. 9, the display device ED-c of FIG. 10, in case that compared to the display device ED-a of FIG. 7A, may further include an adhesive layer AL6 disposed between an impact resistance enhancement layer RFL and an opening pattern OP-PT of a support plate PLT-c. The adhesive layer AL6 disposed between the impact resistance enhancement layer RFL and the opening pattern OP-PT of the support plate PLT-c may be referred to as the second adhesive layer. The contents regarding the above-described adhesive layers AL1, AL2, AL3, AL4, and AL5 may be identically applied to the material of the second adhesive layer AL6. The impact resistance enhancement layer RFL may be coupled (or connected) to the support plate PLT-c through the second adhesive layer AL6. By way of example, the impact resistance enhancement layer RFL may be coupled (or connected) to the opening pattern OP-PT of the support plate PLT-c. Furthermore, as in the display device ED-a of FIG. 7A, the impact resistance enhancement layer RFL may be coupled (or connected) with a panel protection layer PF through a first adhesive layer AL5 of the display device ED-c of FIG. 10. The display module DM-c may include an impact absorbing layer DL, adhesive layers AL3, AL4, and AL5, display panel DP, panel protection layer PF and support plate PLT-c.

In addition to those described above, the same contents as the display device ED-a of FIG. 7A may be applied to the display device ED-c of FIG. 10.

As described above, the display device according to the disclosure may include the impact resistance enhancement layer disposed in the folding region. Accordingly, the display device may have excellent impact resistance and folding reliability.

While the disclosure has been described with reference to embodiments thereof, it will be apparent to those of ordinary skill in the art that various changes and modifications may be made thereto without departing from the spirit and scope of the disclosure as set forth in the following claims.

What is claimed is:

1. A display device comprising:
a display panel including a first non-folding region, a folding region, and a second non-folding region sequentially disposed in a first direction;
a support plate disposed below the display panel, the support plate including a plurality of openings that overlap the folding region in a plan view; and
an impact resistance enhancement layer disposed below the display panel, wherein
the support plate has a groove that overlaps the folding region in a plan view,
the impact resistance enhancement layer is disposed in the groove of the support plate, and
the impact resistance enhancement layer has a modulus in a range of about 3 GPa to about 6 GPa.

2. The display device of claim 1, wherein the impact resistance enhancement layer has a thickness in a range of about 30 μm to about 50 μm.

3. The display device of claim 1, wherein
the support plate includes an upper surface adjacent to the display panel, and
the groove is defined on the upper surface of the support plate.

4. The display device of claim 1, further comprising:
a first adhesive layer directly disposed on the support plate; and
a panel protection layer directly disposed on the first adhesive layer.

5. The display device of claim 4, wherein the impact resistance enhancement layer is connected with the panel protection layer through the first adhesive layer.

6. The display device of claim 5, wherein the impact resistance enhancement layer is not connected with the support plate.

7. The display device of claim 5, further comprising:
a second adhesive layer directly disposed below the impact resistance enhancement layer and that connects the impact resistance enhancement layer and the support plate.

8. The display device of claim 1, further comprising:
an adhesive layer 1-1 directly disposed on the support plate, wherein the adhesive layer 1-1 overlaps the first non-folding region and does not overlap the folding region in a plan view;
an adhesive layer 1-2 directly disposed on the support plate, wherein the adhesive layer 1-2 overlaps the second non-folding region and does not overlap the folding region in a plan view; and
a panel protection layer directly disposed on the adhesive layer 1-1 and the adhesive layer 1-2.

9. The display device of claim 8, further comprising:
a second adhesive layer disposed below the impact resistance enhancement layer and that connects the impact resistance enhancement layer and the support plate.

10. The display device of claim 9, wherein the impact resistance enhancement layer is not connected with the panel protection layer.

11. A display device comprising:
a display panel including a first non-folding region, a folding region, and a second non-folding region sequentially disposed in a first direction;
a support plate disposed below the display panel, the support plate including a plurality of openings that overlap the folding region in a plan view; and
an impact resistance enhancement layer disposed below the display panel, wherein
the support plate has a groove that overlaps the folding region in a plan view,
the impact resistance enhancement layer is disposed in the groove of the support plate, and
the impact resistance enhancement layer has a thickness in a range of about 30 μm to about 50 μm.

12. The display device of claim 11, wherein the impact resistance enhancement layer has a modulus in a range of about 3 GPa to about 6 GPa.

13. The display device of claim 11, wherein
the support plate includes an upper surface adjacent to the display panel, and
the groove is defined on the upper surface of the support plate.

14. The display device of claim 11, further comprising:
a first adhesive layer directly disposed on the support plate; and
a panel protection layer directly disposed on the first adhesive layer,
wherein the impact resistance enhancement layer is connected with the panel protection layer through the first adhesive layer.

15. The display device of claim 11, further comprising:
an adhesive layer 1-1 directly disposed on the support plate, wherein the adhesive layer 1-1 overlaps the first non-folding region and does not overlap the folding region in a plan view;
an adhesive layer 1-2 directly disposed on the support plate, wherein the adhesive layer 1-2 overlaps the second non-folding region and does not overlap the folding region in a plan view;
a panel protection layer directly disposed on the adhesive layer 1-1 and the adhesive layer 1-2; and
a second adhesive layer disposed below the impact resistance enhancement layer and that connects the impact resistance enhancement layer and the support plate.

16. The display device of claim 11, further comprising:
a first adhesive layer directly disposed on the support plate;
a panel protection layer directly disposed on the first adhesive layer; and
a second adhesive layer directly disposed below the impact resistance enhancement layer and that connects the impact resistance enhancement layer and the support plate.

17. A display device comprising:
a display panel including a first non-folding region, a folding region, and a second non-folding region sequentially disposed in a first direction;
a support plate disposed below the display panel, the support plate including a plurality of openings that overlap the folding region in a plan view; and
an impact resistance enhancement layer disposed below the display panel, wherein
the support plate includes an upper surface adjacent to the display panel,
the support plate has a groove on the upper surface that overlaps the folding region in a plan view, and
the impact resistance enhancement layer is disposed in the groove of the support plate.

18. The display device of claim 17, wherein the impact resistance enhancement layer has a modulus in a range of about 3 GPa to about 6 GPa.

19. The display device of claim 17, wherein the impact resistance enhancement layer has a thickness in a range of about 30 μm to about 50 μm.

20. The display device of claim 17, further comprising:
a first adhesive layer directly disposed on the support plate; and
a panel protection layer directly disposed on the first adhesive layer.
